(19) United States
(12) Patent Application Publication
(10) Pub. No.: US 2007/0108549 A1
(43) Pub. Date: May 17, 2007

(54) SEMICONDUCTOR STRUCTURE

(76) Inventor: Ping-Chang Wu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,210

(22) Filed: Nov. 15, 2005

(51) Int. Cl. H01L 29/00

(52) U.S. Cl. 257/529

(57) ABSTRACT

A semiconductor structure is disclosed. The semiconductor structure includes a substrate, a bond pad, a fuse structure and a protection layer. The substrate has a pad region and a fuse region. The bond pads are disposed in the pad region of the substrate. The fuse structure is disposed in the fuse region of the substrate. The protection layer is disposed on the substrate to cover the pad region and the fuse region so that the bond pads are prevented from oxidation.

### BACKGROUND OF THE INVENTION

1. Field of the Invention

The present invention relates to a semiconductor structure and processing method therefor. More particularly, the present invention relates to a semiconductor structure and processing method therefor that can prevent the oxidation of exposed bond pads.

2. Description of the Related Art

In a general wafer manufacturing process, the wafer, after the front-end process for fabricating the semiconductor device (such as integrated circuit designs) is finished, is sent to a packaging factory for post-engineering process such as packaging or testing.

FIG. 1 is a schematic cross-sectional view of a conventional semiconductor structure just before being packaged. As shown in FIG. 1, a protection layer 106 is formed over the substrate 100 to cover the bond pads 102 and fuse structures 104 already formed thereon before packaging the wafer. The substrate 100 includes metal oxide semiconductor (MOS) transistor structures, leading wires or other semiconductor devices (not shown) formed in a common semiconductor process. Then, the photolithographic and etching process is performed twice. In one photolithographic and etching process, an opening 108 is formed in the protection layer 106 of the pad region 101 to expose the bond pad 102. In another photolithographic and etching process, another opening 110 is formed in the protection layer 106 of the fuse region 103 so that a portion of the protection layer remains on the fuse structure 104 to serve as a structure for a subsequent laser repair process. After that, the wafer is sent to a packaging factory for other back-end operations.

However, when sending the wafer to the packaging factory, the exposed bond pads 102 are in contact with the outside environment such that the bond pads 102 are easily oxidized or damaged. Therefore, the time limit for the bond pads 102 exposed to the outside environment is often limited to seven days. Moreover, as two photomasks are required to form the openings 108 and 110, more time is wasted and the production cost is increased. Furthermore, for the laser repairing process to yield optimum results, the process of etching the fuse region 103 must be performed meticulously and carefully to control the thickness of the protection layer 106 on the fuse structure.

### SUMMARY OF THE INVENTION

Accordingly, at least one objective of the present invention is to provide a semiconductor structure that can prevent the bond pads of the semiconductor structure from oxidation due to contact with the outside environment.

At least a second objective of the present invention is to provide a semiconductor structure that can prevent the bond pads of the semiconductor structure from damages when the wafer are being transported.

At least a third objective of the present invention is to provide a processing method for a semiconductor structure using fewer number of photomasks.

At least a fourth objective of the present invention is to provide a processing method for a semiconductor structure that can reduce the production cost and the processing time.

To achieve these and other advantages and in accordance with the purpose of the invention, as embodied and broadly described herein, the invention provides a semiconductor structure. The semiconductor structure comprises a substrate, a bond pad, a fuse structure, and a protection layer. The substrate has a pad region and a fuse structure. The bond pad is disposed in the pad region of the substrate. The fuse structure is disposed in the fuse region of the substrate. The protection layer is disposed on the substrate to cover the pad region and the fuse region.

According to the semiconductor structure in the embodiment of the present invention, the protection layer has a thickness between about 500 Å˜1000 Å, for example.

According to the semiconductor structure in the embodiment of the present invention, the protection layer is fabricated using an insulating material, for example.

According to the semiconductor structure in the embodiment of the present invention, the bond pads are fabricated using copper, for example.

According to the semiconductor structure in the embodiment of the present invention, the fuse structure is fabricated using copper, for example.

The present invention also provides an alternative semiconductor structure. The semiconductor structure comprises a substrate, a bond pad, a fuse structure, a first protection layer and a second protection layer. The substrate has a pad region and a fuse region. The bond pad is disposed in the pad region of the substrate. The fuse structure is disposed in the fuse region of the substrate. The first protection layer is disposed on the substrate to expose the bond pad and the fuse structure. The second protection layer is disposed on the substrate to cover the first protection layer, the bond pad and the fuse structure.

According to the semiconductor structure in the embodiment of the present invention, the second protection layer has a thickness between about 500 Å˜1000 Å, for example.

According to the semiconductor structure in the embodiment of the present invention, the second protection layer is fabricated using an insulating material, for example.

According to the semiconductor structure in the embodiment of the present invention, the first protection layer is a silicon oxide layer, a silicon nitride layer or a composite layer comprising a silicon oxide layer and a silicon nitride, for example.

According to the semiconductor structure in the embodiment of the present invention, the first protection layer has a thickness between about 4000 Å˜5000 Å, for example.

According to the semiconductor structure in the embodiment of the present invention, the bond pad is fabricated using copper, for example.

According to the semiconductor structure in the embodiment of the present invention, the fuse structure is fabricated using copper, for example.

The present invention also provides a processing method for a semiconductor structure. First, a substrate is provided. The substrate has a pad region and a fuse region. The substrate has a bond pad already formed in the pad region and a fuse structure already formed in the fuse region. Then, at least a testing operation is carried out. After that, a first protection layer is formed on the substrate to cover the pad region and the fuse region.

According to the processing method for the semiconductor structure in the embodiment of the present invention, the first protection layer has a thickness between about 500 Å˜1000 Å, for example.

According to the processing method for the semiconductor structure in the embodiment of the present invention, the first protection layer is fabricated using an insulating material, for example.

According to the processing method for the semiconductor structure in the embodiment of the present invention, at least a testing operation comprises an electrical testing operation or a first yield inspection process, for example.

According to the processing method for the semiconductor structure in the embodiment of the present invention, the electrical testing operation includes a wafer acceptance test (WAT), for example.

According to the processing method for the semiconductor structure in the embodiment of the present invention, after performing the first yield inspection process but before forming the first protection layer, the processing method may further include performing a laser repair operation and performing a second yield inspection process.

According to the processing method for the semiconductor structure in the embodiment of the present invention, before performing at least a testing operation, the processing method may further include forming a second protection layer on the substrate that exposes the bond pad and the fuse structure.

The present invention also provides an alternative processing method for a semiconductor structure. First, a substrate is provided. The substrate has a pad region and a fuse region. The substrate has a bond pad already formed in the pad region and a fuse structure already formed in the fuse region. Then, a first testing operation is carried out. Thereafter, a first protection layer is formed on the substrate to cover the pad region and the fuse region. After that, the first protection layer on the bond pad is removed to form a pad opening. Then, a second testing operation is performed.

According to the processing method for the semiconductor structure in the embodiment of the present invention, the first protection layer has a thickness between about 500 Å˜1000 Å, for example.

According to the processing method for the semiconductor structure in the embodiment of the present invention, the first protection layer is fabricated using an insulating material, for example.

According to the processing method for the semiconductor structure in the embodiment of the present invention, the first testing operation includes an electrical testing operation, for example.

According to the processing method for the semiconductor structure in the embodiment of the present invention, the electrical testing operation includes a wafer acceptance test, for example.

According to the processing method for the semiconductor structure in the embodiment of the present invention, the second testing operation includes a first yield inspection process, for example.

According to the processing method for the semiconductor structure in the embodiment of the present invention, after performing the first yield inspection process, the processing method may further include performing a laser repair operation and performing a second yield inspection process.

According to the processing method for the semiconductor structure in the embodiment of the present invention, before performing the first testing operation, the processing method may further include forming a second protection layer on the substrate that exposes the bond pad and the fuse structure.

In the semiconductor structure of the present invention, a protection layer is disposed on the substrate to cover the bond pad and the fuse structure simultaneously. Hence, the bond pad is prevented from exposure to moisture in the outside environment to cause oxidation. Furthermore, the thickness of the protection layer above the fuse structure is easier to control so that the optimum laser repairing results can be obtained. Moreover, in the process for the semiconductor structure, there is no need to form two different openings in the pad region and the fuse region. Consequently, the etching operation needs not be performed twice; in other words, it doesn't require two photomasks for two etching operations. Ultimately, the processing time and production cost is saved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional semiconductor structure before a packaging process.

FIG. 2A is a schematic cross-sectional view of a semiconductor structure according to one embodiment of the present invention.

FIG. 2B is a schematic cross-sectional view of a semiconductor structure according to another embodiment of the present invention.

FIGS. 3A through 3C are schematic cross-sectional views showing the processing method for a semiconductor structure according to one embodiment of the present invention.

FIGS. 4A through 4C are schematic cross-sectional views showing the processing method for a semiconductor structure according to another embodiment of the present invention.

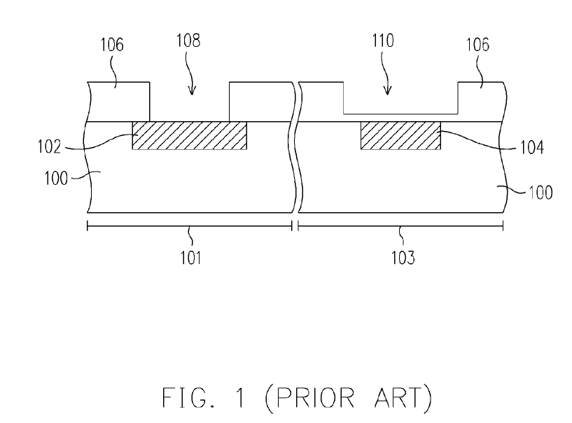

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

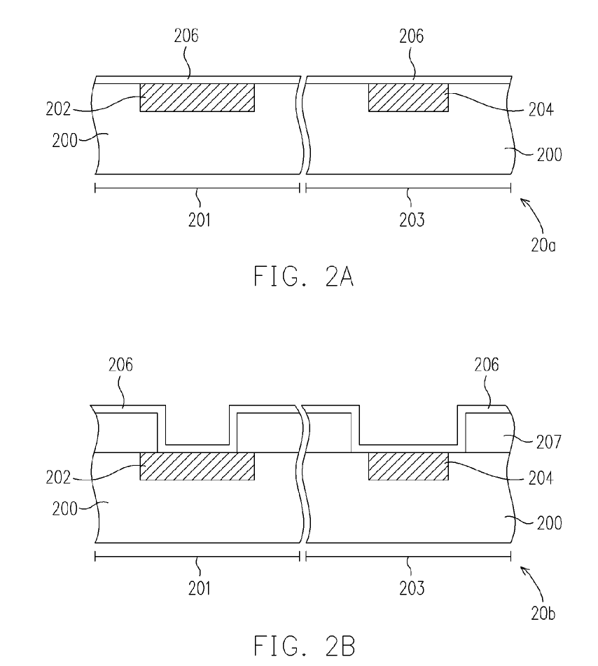

FIG. 2A is a schematic cross-sectional view of a semiconductor structure according to one embodiment of the present invention. The semiconductor structure 20a as shown in FIG. 2A comprises a substrate 200, a bond pad 202, a fuse structure 204 and a protection layer 206. The substrate 200 has a pad region 201 and a fuse region 203. The bond pad 202 is disposed in the pad region 201 of the substrate 200. The bond pad 202 is fabricated using copper, for example. The fuse structure 204 is disposed in the fuse region 203 of the substrate 200. The fuse structure 204 is fabricated using copper, for example. The protection layer 206 is disposed on the substrate 200 to cover the pad region 201 and the fuse region 203. The protection layer 206 has a thickness between about 500 Å˜1000 Å and is fabricated using silicon oxide, silicon nitride, silicon oxynitride or a typical insulating material, for example. It should be noted that the protection layer 206 on the bond pad 202 could prevent the bond pad 202 from being oxidized due to exposure to the surrounding moisture when the wafer is transported to a packaging factory. Thereafter, for the subsequent processes after arriving at a packaging factory, the protection layer 206 is removed from the bond pad 202 to form a bond pad opening. Moreover, the protection layer 206 on the fuse structure 204 can be used in a subsequent laser repair operation.

FIG. 2B is a schematic cross-sectional view of a semiconductor structure according to another embodiment of the present invention. As shown in FIG. 2B, one major difference between the semiconductor structure 20b in the present embodiment and the semiconductor structure 20a is that the semiconductor structure 20b has an additional protection layer 207 disposed on the substrate 200. Furthermore, the bond pad 202 and the fuse structure 204 are exposed. The protection layer 206 is disposed on the substrate 200 to cover the protection layer 207, the bond pad 202 and the fuse structure 204. The protection layer 207 is a silicon oxide layer, a silicon nitride layer or a composite layer comprising a silicon oxide layer and a silicon nitride layer. The protection layer 207 has a thickness between about 4000 Å˜5000 Å, for example. In the present embodiment, the protection layer 207 can prevent particles generated in a laser repairing operation in the fuse region 203 from dropping on the pad region 210 and affecting the yield of the product.

In the following, the semiconductor structure 20b is used as an example to describe the process before carrying out the wafer packaging operation.

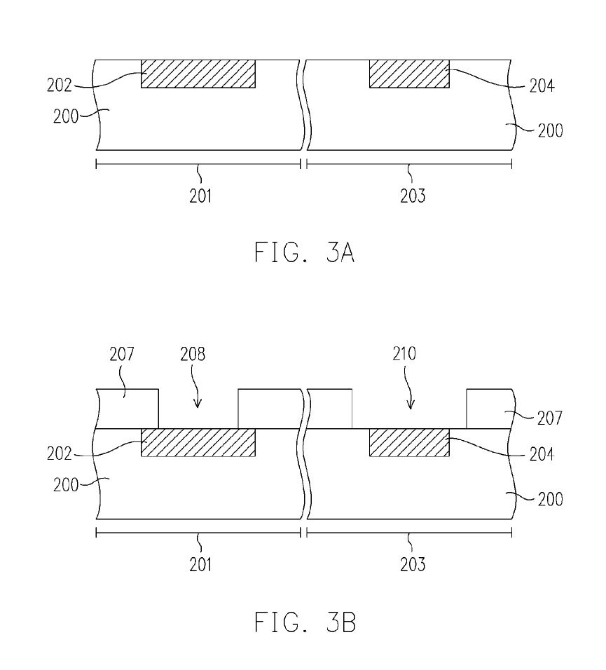

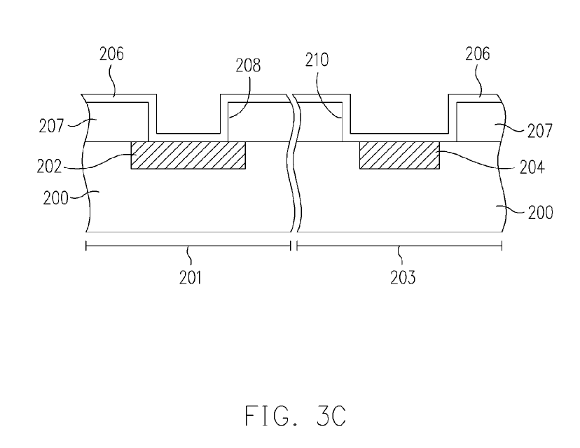

FIGS. 3A through 3C are schematic cross-sectional views showing the processing method for a semiconductor structure according to one embodiment of the present invention. First, as shown in FIG. 3A, a substrate 200 is provided. The substrate 200 has a pad region 201 and a fuse region 203. Furthermore, a bond pad 202 has been already formed in the pad region 201 of the substrate 200 and a fuse structure 204 has been already formed in the fuse region 203 of the substrate 200. In addition, the substrate 200 may further include metal-oxide-semiconductor (MOS) transistor structures, leading wires or other semiconductor devices (not shown) formed in a conventional semiconductor process.

As shown in FIG. 3B, a protection layer 207 is formed on the substrate 200. Then, an etching operation is performed to form an opening 208 in the pad region 201 that exposes the bond pad 202 and another opening 210 in the fuse region 203 that exposes the fuse structure 204. It should be noted that the openings 208 and 210 are simultaneously formed in the same etching process. Hence, only one photomask is required. In other words, both the processing time and production cost are reduced.

Thereafter, an electrical testing operation is performed on the pad region 201. The electrical testing operation is a wafer acceptance test, for example. After that, a first yield inspection process is performed. When defects are found in the wafer, a laser repairing operation is carried out in the fuse region 203. Then, a second yield inspection process is carried out to check for any additional defects after the laser repairing operation.

As shown in FIG. 3C, another protection layer 206 is formed on the substrate to cover the protection layer 207, the bond pad 202 and the fuse structure 204. Thereafter, the wafer is transported to a packaging factory for back-end processes. Since a protection layer 206 has already been formed over the bond pad 202, the bond pad 202 is prevented from oxidation due to contact with the outside environment. In addition, after forming the protection layer 206, the queue time of the wafer can be increased. In other words, the 7-day limit for the subsequent packaging operation can be relaxed.

In another embodiment, the step for forming the protection layer 207 can be skipped. Instead, a yield inspection process is directly performed after forming the bond pad 202 and the fuse structure 204 and the protection layer 206 is formed over the substrate 200 thereafter.

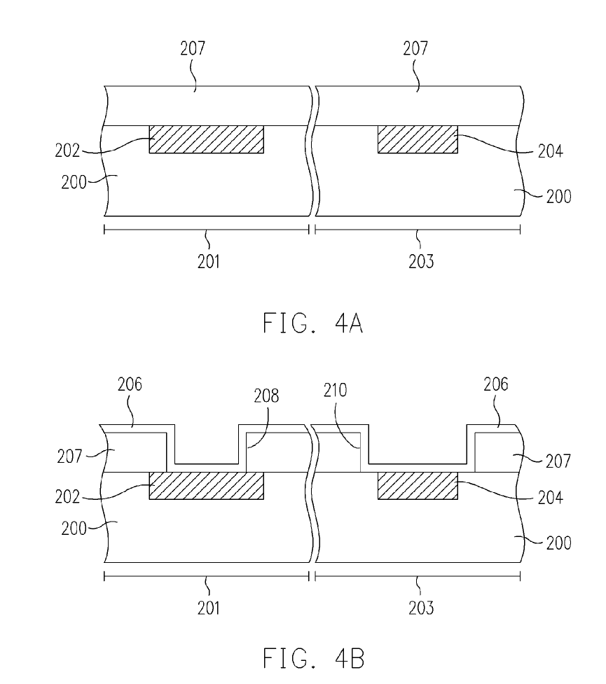

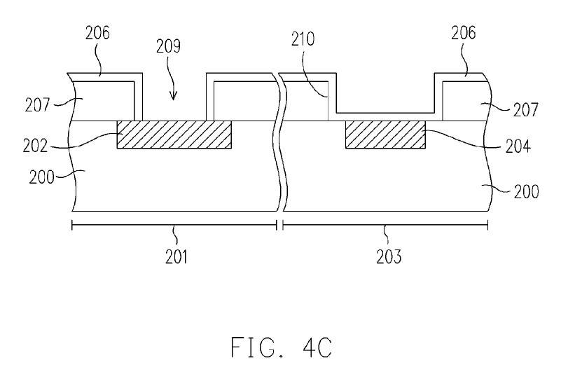

FIGS. 4A through 4C are schematic cross-sectional views showing the processing method for a semiconductor structure according to another embodiment of the present invention. First, as shown in FIG. 4A, a substrate 200 is provided. The substrate 200 has a pad region 201 and a fuse region 203. Furthermore, a bond pad 202 has already been formed in the pad region 201 of the substrate 200 and a fuse structure 204 has already been formed in the fuse region 203 of the substrate 200. Then, a protection layer 207 is formed on the substrate 200.

As shown in FIG. 4B, an etching operation is carried out to form an opening 208 in the pad region 201 to expose the bond pad 202 and another opening 210 in the fuse region 203 to expose the fuse structure 204. Then, an electrical testing operation is performed on the pad region 201. The electrical testing operation is a wafer acceptance test, for example. Thereafter, a protection layer 206 is formed over the substrate 200 to cover the pad region 201 and the fuse region 203.

As shown in FIG. 4C, the wafer is transported to a packaging factory for other back-end processes. First, the protection layer 206 over the bond pad 202 is removed to form a bond pad opening 209. Then, a first yield inspection process is performed on the bond pad 202. If defects are found in the wafer, a laser repairing operation is performed in the fuse region 203. Thereafter, a second yield inspection process is performed to check for any additional defects after the laser repairing operation. Finally, other subsequent packaging processes are carried out on the wafer.

Similarly, in another embodiment, the step for forming the protection layer 207 can be skipped. Instead, the electrical testing process can be directly carried out after forming the bond pad 202 and the fuse structure 204.

In summary, the semiconductor structure of the present invention has a protection layer disposed on the substrate to cover the bond pad and the fuse structure simultaneously. Hence, the bond pad is prevented from oxidation due to exposure to air. Furthermore, the thickness of the protection layer above the fuse structure is easier to control so that the best laser repairing results can be obtained after a laser repair operation. Moreover, in the process of forming the semiconductor structure, the opening in the pad region and the fuse region can be formed in the protection layer in a single etching operation. Consequently, only one photomask is required. As a result, the processing time and the production cost are reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor structure, comprising:
a substrate having a pad region and a fuse region;
a bond pad disposed in the pad region of the substrate;
a fuse structure disposed in the fuse region of the substrate; and
a protection layer disposed on the substrate to cover the pad region and the fuse region.

2. The semiconductor structure of claim 1, wherein the protection layer has a thickness between about 500 Å˜1000 Å.

3. The semiconductor structure of claim 1, wherein the material constituting the protection layer includes an insulating material.

4. The semiconductor structure of claim 1, wherein the material constituting the bond pad includes copper.

5. The semiconductor structure of claim 1, wherein the material constituting the fuse structure includes copper.

6. A semiconductor device, comprising:
a substrate having a pad region and a fuse region;
a bond pad disposed in the pad region of the substrate;
a fuse structure disposed in the fuse region of the substrate;
a first protection layer disposed on the substrate to expose the bond pad and the fuse structure; and
a second protection layer disposed on the substrate to cover the first protection layer, the pad region and the fuse region.

7. The semiconductor structure of claim 6, wherein the second protection layer has a thickness between about 500 Å˜1000 Å.

8. The semiconductor structure of claim 6, wherein the material constituting the second protection layer includes an insulating material.

9. The semiconductor structure of claim 6, wherein the first protection layer includes a silicon oxide layer, a silicon nitride layer or a composite layer comprising a silicon oxide layer and a silicon nitride layer.

10. The semiconductor structure of claim 6, wherein the protection layer has a thickness between about 4000 Å˜5000 Å.

11. The semiconductor structure of claim 6, wherein the material constituting the bond pad includes copper.

12. The semiconductor structure of claim 6, wherein the material constituting the fuse structure includes copper.

13-27. (canceled)
